(19) United States
(12) Patent Application Publication
(10) Pub. No.: US 2004/0164298 A1
(43) Pub. Date: Aug. 26, 2004

(54) Semiconductor structure, semiconductor device, and method and apparatus for manufacturing the same

(76) Inventors: Masato Hiramatsu, Yokohama-shi (JP); Yoshinobu Kimura, Yokohama-shi (JP); Hiroyuki Ogawa, Yokohama-shi (JP); Masayuki Jyumonji, Yokohama-shi (JP); Yoshitaka Yamamoto, Yokohama-shi (JP); Masakiyo Matsumura, Yokohama-shi (JP)

Correspondence Address: OBLON, SPIVAK, MCCLELLAND, MAIER & NEUSTADT, P.C., 1940 DUKE STREET, ALEXANDRIA, VA, 22314, US

(21) Appl. No.: 10/722,486

(22) Filed: Nov. 28, 2003

(30) Foreign Application Priority Data
Nov. 29, 2002 (JP) 2002-346806
Apr. 25, 2003 (JP) 2003-121772

(51) Int. Cl. H01L 29/76

(52) U.S. Cl. 257/66

(57) ABSTRACT

A semiconductor device includes a non-single-crystal semiconductor film, a support substrate that supports the non-single-crystal semiconductor film, and an active device having a part of the non-single-crystal semiconductor film as a channel region. In particular, the channel region has an oxygen concentration not higher than 1×10¹⁸ atoms/cm³ and a carbon concentration not higher than 1×10¹⁸ atoms/cm³.

### CROSS-REFERENCE TO RELATED APPLICATIONS

This application is based upon and claims the benefit of priority from the prior Japanese Patent Applications No. 2002-346806, filed Nov. 29, 2002; and No. 2003-121772, filed Apr. 25, 2003, the entire contents of both of which are incorporated herein by reference.

### BACKGROUND OF THE INVENTION

1. Field of the Invention

The present invention relates to a semiconductor structure in which a non-single-crystal semiconductor film is supported on a support substrate, a semiconductor device, and a method and an apparatus for manufacturing the same.

2. Description of the Related Art

In recent years, in active-matrix liquid crystal display apparatuses, a polycrystalline semiconductor. thin-film transistor has been used as a pixel switching element. The polycrystalline semiconductor thin-film transistor has a channel region disposed within a polycrystalline semiconductor film including a plurality of crystal grains. Carriers (i.e., electrons and holes) through the channel region of the polycrystalline semiconductor film are movable at a speed about 10 to 100 times higher than carriers within a channel region disposed within an amorphous semiconductor film. Accordingly, the polycrystalline semiconductor thin-film transistor operates at high speed as a pixel switching element. A video processing circuit may be formed of a group of similar polycrystalline semiconductor thin-film transistors and built into a liquid crystal display apparatus. Thereby, an arithmetic operation time, which is needed in accordance with an increase in the number of pixels, can be reduced.

A polycrystalline semiconductor film can be obtained by melting and recrystallizing a semiconductor film of, e.g., amorphous silicon by, for instance, an excimer laser crystallization method. Conventionally, the excimer laser crystallization method has widely been used since a crystal grain, which will grow into a semiconductor film, can be grown to a large grain size, and the number of crystal grain boundaries that hinder motion of carriers can be greatly reduced.

Fabrication steps for a polycrystalline semiconductor thin-film transistor will now be described. FIGS. 1A to 1F illustrate fabrication steps for a polysilicon thin-film transistor, which is an example of the polycrystalline semiconductor thin-film transistor. A channel region of the polysilicon thin-film transistor is located within a polysilicon film formed by using the aforementioned excimer laser crystallization method.

In a step illustrated in FIG. 1A, an underlying insulation layer 102 is formed on a glass substrate 101. An amorphous silicon film 103 is formed on the underlying insulation layer 102. The amorphous silicon film 103 is then subjected to dehydrogenation treatment.

In a step depicted in FIG. 1B, the glass substrate 101 is moved in the direction indicated by an arrow 105. An excimer laser beam is applied to the amorphous silicon film 103 that moves along with the glass substrate 101. By the laser beam scanning, the amorphous silicon film 103 is melted and recrystallized into a polysilicon film 106, as shown in FIG. 1C.

In a step of FIG. 1D, only a specific region of the polysilicon film 106, which is necessary as a part of a thin-film transistor, is left and the other regions of the polysilicon film 106 are removed from the underlying insulation layer 102. Then, a gate insulation film 107 is formed to cover the polysilicon film 106 and underlying insulation layer 102.

In a step shown in FIG. 1E, a gate electrode layer 110 is formed on the gate insulation film 107. The gate electrode layer 110 serves also as a mask for doping the polysilicon film 106 with n-type or p-type impurities. The impurities are introduced into the polysilicon film 106 through the gate insulation film 107. Thereby, a source region 108 and a drain region 109, which are located on both sides of the gate electrode layer 110, are formed within the polysilicon film 106.

In a step depicted in FIG. 1F, an interlayer insulation film 111 is formed to cover the gate insulation film 107 and gate electrode layer 110. Then, heat treatment is performed to activate the impurities in the source region 108 and drain region 109. The gate insulation film 107 and interlayer insulation film 111 are partly removed so as to form a pair of contact holes that expose the source region 108 and drain region 109. A source electrode layer 112 and a drain electrode layer 113 are formed so as to electrically contact the source region 108 and drain region 109, respectively, via the contact holes. A metal wiring layer 114 is formed in contact with the drain electrode layer 113 as wiring for transmitting an electrical signal to the thin-film transistor.

The polysilicon thin-film transistor is manufactured through the above-described fabrication steps. In the thin-film transistor, a gate voltage is applied to the gate electrode layer 110, thereby to control a current flowing through a channel region 115 provided between the source region 108 and drain region 109. This polysilicon thin-film transistor and the method of manufacturing the same are disclosed, for instance, in Jpn. Pat. Appln. KOKAI Publication No. 2002-289865, pp. 4-5, and FIG. 1.

The structure and the manufacturing method of the prior-art polycrystalline semiconductor thin-film transistor, however, have some factors that would degrade the electrical characteristics of the-thin-film transistor. These factors are important when the thin-film transistor is applied to a liquid crystal display apparatus.

The following are results of the study by the inventor of the present invention.

(1) The channel region includes impurity elements that lead to atomic-structural defects. The defects function as traps for carriers that effect electric conduction. Consequently, motion of carriers within the channel region is hindered. These impurity elements are contaminants that should be essentially distinguished from impurity elements introduced in the source and drain regions. Specifically, the contaminant impurity elements are elements (light elements) such as oxygen and carbon contained in the air. Such elements remain within a film-forming chamber of a conventional semiconductor manufacturing apparatus and mix in a semiconductor film during the film-forming process.

(2) In addition, metal elements, which are components of the inner wall material of the film-forming chamber, float within the film-forming chamber in the state in which they are physically or chemically separated or released. These elements, too, mix in the semiconductor film during the film-forming process and change the electrical characteristics of the semiconductor. Examples of such metal elements are chromium, potassium, sodium, aluminum, calcium, titanium, zinc, cobalt, copper, iron, nickel, molybdenum, manganese, vanadium, and tungsten.

(3) A support substrate for a semiconductor film is a glass substrate heat-resistant to a temperature of about 600° C. An annealless glass substrate or a plastic substrate may be used as the support substrate, but the heat resistance thereof is lower. A gettering process for removing the aforementioned light elements or metal elements from the semiconductor film requires high temperatures that exceed the heat resistance of the support substrate. Thus, the gettering process cannot be applied to the support substrate.

Jpn. Pat. Appln. KOKAI Publication No. 2002-289865 discloses that good characteristics can be obtained by reducing the number of atoms of impurity elements such as oxygen and nitrogen to 5×10¹⁸ per cm³ or less, and preferably to 5×10¹⁸ per cm³. However, this concentration refers to a single light element, and no consideration is given to the relationship between a plurality of light elements and micro-defects in the atomic structure of the semiconductor film.

### BRIEF SUMMARY OF THE INVENTION

The object of the present invention is to provide a semiconductor structure, a semiconductor device, and a method and an apparatus for manufacturing the same, which can enhance electrical characteristics of an active device.

According to a first aspect of the present invention, there is provided a semiconductor structure comprising a non-single-crystal semiconductor film including a channel region for an active device, and a support substrate that supports the non-single-crystal semiconductor film, the channel region having an oxygen concentration not higher than 1×10¹⁸ atoms/cm³ and a carbon concentration not higher than 1×10¹⁸ atoms/cm³.

According to a second aspect of the present invention, there is provided a manufacturing method for a semiconductor structure having a non-single-crystal semiconductor film including a channel region for an active device, and a support substrate that supports the non-single-crystal semiconductor film, the method comprising subjecting an inner wall of a film-forming chamber to a surface etching process with a fluorine-based gas, coating the inner wall with an amorphous semiconductor film with a thickness of 50 to 1000 nm, placing the support substrate in the film-forming chamber and forming the non-single-crystal semiconductor film, and melting and recrystallizing the non-single-crystal semiconductor film by heating.

According to a third aspect of the present invention, there is provided a manufacturing apparatus for a semiconductor structure having a non-single-crystal semiconductor film including a channel region for an active device, and a support substrate that supports the non-single-crystal semiconductor film, the apparatus comprising a film-forming unit that accommodates the support substrate in a film-forming chamber and forms the non-single-crystal semiconductor film, and a crystallizing unit that melts and recrystallizes the non-single-crystal semiconductor film, the film-forming chamber having an inner wall formed of a metal containing aluminum.

According to a fourth aspect of the present invention, there is provided a semiconductor device comprising a non-single-crystal semiconductor film, a support substrate that supports the non-single-crystal semiconductor film, and an active device having a part of the non-single-crystal semiconductor film as a channel region, the channel region having an oxygen concentration not higher than 1×10¹⁸ atoms/cm³ and a carbon concentration not higher than 1×10¹⁸ atoms/cm³.

According to a fifth aspect of the present invention, there is provided a semiconductor device comprising a non-single-crystal semiconductor film, a support substrate that supports the non-single-crystal semiconductor film, and an active device having a part of the non-single-crystal semiconductor film as a channel region, the channel region having an oxygen concentration not higher than 1×10¹⁸ atoms/cm³ and a stacking fault density not higher than 1×10⁶ cm⁻³.

According to a sixth aspect of the present invention, there is provided a manufacturing method for a semiconductor device having a non-single-crystal semiconductor film, a support substrate that supports the non-single-crystal semiconductor film, and an active device having a part of the non-single-crystal semiconductor film as a channel region, the method comprising subjecting an inner wall of a film-forming chamber to a surface etching process with a fluorine-. based gas, coating the inner wall with an amorphous semiconductor film with a thickness of 50 to 1000 nm, placing the support substrate in the film-forming chamber and forming the non-single-crystal semiconductor film, and melting and recrystallizing the non-single-crystal semiconductor film, thus forming the active device having the part of the non-single-crystal semiconductor film as the channel region.

In these semiconductor structure and devices, the channel region has an oxygen concentration and a carbon concentration, each of which is not higher than 1×10¹⁸ atoms/cm³. If at least the channel region of the non-single-crystal semiconductor film has such an oxygen concentration and a carbon concentration, microdefects occurring in the crystalline structure of the channel region due to these elements can be reduced to a very small value of about 1×10⁶/cm⁻³, which is practically tolerable. Thereby, the carriers in the channel region can move at high speed without being considerably hindered by microdefects. Therefore, the electrical characteristics of the active device can be enhanced.

Besides, in the manufacturing method for the semiconductor structure and the manufacturing method for the semiconductor device, the inner wall of the film-forming chamber is subjected to surface etching treatment using a fluorine-based gas, and the surface of the inner wall is coated with an amorphous semiconductor film having a thickness of 50 to 1000 nm. Thereby, the contaminant elements are removed from the surface of the inner wall of the film-forming chamber by the surface etching treatment, and the amorphous semiconductor film prevents the fluorine included in the inner wall by the surface etching treatment from being released to the inside space of the film-forming chamber. Therefore, the contaminant mixing in the non-single-crystal semiconductor film in the making can be reduced, and the electrical characteristics of the active device can be enhanced.

Furthermore, in the manufacturing method for the semiconductor structure, the film-forming chamber has the inner wall formed of a metal containing aluminum. Thus, when cleaning using a fluorine-based gas is performed, aluminum that is a metal component of the inner wall is combined with fluorine, and a fluorine component is produced. When aluminum and fluorine are included in the inner wall as a fluorine compound, it is possible to prevent the aluminum and fluorine from being released from the inner wall of the film-forming chamber to the inside space of the film-forming chamber and mixing as contaminant into the non-single-crystal semiconductor film in the making. Therefore, the electrical characteristics of the active device can be enhanced.

Additional objects and advantages of the invention will be set forth in the description which follows, and in part will be obvious from the description, or may be learned by practice of the invention. The objects and advantages of the invention may be realized and obtained by means of the instrumentalities and combinations particularly pointed out hereinafter.

### BRIEF DESCRIPTION OF THE SEVERAL VIEWS OF THE DRAWING

The accompanying drawings, which are incorporated in and constitute a part of the specification, illustrate embodiments of the invention, and together with the general description given above and the detailed description of the embodiments given below, serve to explain the principles of the invention.

FIG. 1A to FIG. 1F are cross-sectional views illustrating fabrication steps for a conventional polysilicon thin-film transistor;

FIG. 2 shows a cross-sectional structure of a semiconductor device according to an embodiment of the present invention;

FIG. 3 is a table showing doses of carbon and oxygen implanted in samples of amorphous silicon films, aiming at verifying the correlation between carbon and is oxygen in the semiconductor film shown in FIG. 2, on the one hand, and a stacking fault density, on the other hand;

FIG. 4 is a table showing carbon and oxygen concentrations obtained in the amorphous silicon film relative to the doses indicated in FIG. 3;

FIG. 5 is a graph showing the oxygen concentration dependence of stacking fault density, using the carbon concentrations shown in FIG. 4 as parameters;

FIG. 6 is a table showing doses of carbon, oxygen and nickel (metal element) implanted in samples, aiming at verifying the correlation between the carbon, oxygen and metal element in the semiconductor film shown in FIG. 2, on the one hand, and a stacking fault density, on the other hand;

FIG. 7 is a table showing nickel concentrations obtained relative to the doses of nickel indicated in FIG. 6;

FIG. 8 is a graph showing the carbon and oxygen concentration dependence of stacking fault density, using the nickel concentrations shown in FIG. 7 as parameters;

FIG. 9 schematically shows a manufacturing apparatus for use in fabricating the semiconductor device shown in FIG. 2;

FIG. 10 schematically shows a reactor chamber and a plasma generation source shown in FIG. 9;

FIG. 11 shows a cap layer formed in the fabrication of the semiconductor device shown in FIG. 2;

FIG. 12 schematically shows a laser beam applying device for use in melting and recrystallizing an amorphous silicon film shown in FIG. 11;

FIG. 13 shows the relationship between the structure of a phase shifter shown in FIG. 12 and the intensity distribution of a laser beam that has passed through the phase shifter;

FIG. 14 is a graph showing a mass spectrum for identifying residual gases in the reactor chamber shown in FIG. 10;

FIG. 15 is a graph showing results of measurement of ion current of major residual gases within the reactor chamber shown in FIG. 10, relative to a reactor outgas rate;

FIG. 16 is a graph showing a profile of measured depth-directional oxygen concentrations in samples in which silicon films used for the semiconductor film shown in FIG. 2 are deposited at four deposition rates;

FIG. 17 is a graph demonstrating that the relationship between the concentration of silane gas introduced as a material gas into the reactor chamber shown in FIG. 10 and the oxygen concentration in the silicon film depends on the leakage rate of material gas;

FIG. 18 is a graph demonstrating that the proportional relationship between an inverse number of the flow rate of silane gas introduced as material gas in the reactor chamber shown in FIG. 10 and the oxygen concentration in the silicon film is defined by a characteristic straight line with an inclination proportional to the flow rate of contaminant gas caused by outgas;

FIG. 19 is a graph showing, in enlarged scale, a range encircled in FIG. 17;

FIG. 20 shows a cross-sectional structure of a first modification of the semiconductor device shown in FIG. 2; and

FIG. 21 shows a cross-sectional structure of a second modification of the semiconductor device shown in FIG. 2.

### DETAILED DESCRIPTION OF THE INVENTION

A semiconductor device according to an embodiment of the present invention will now be described with reference to the accompanying drawings. This semiconductor device, when used, is built in, for example, an active matrix type liquid crystal display apparatus.

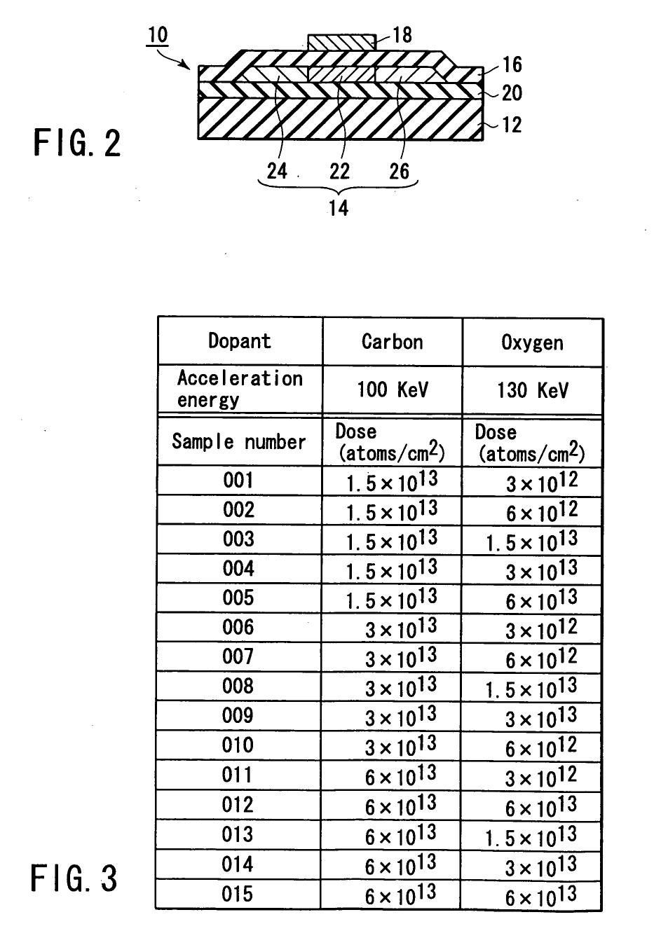

FIG. 2 shows a cross-sectional structure of this semiconductor device. The semiconductor device comprises at least one active device 10, a support substrate 12, and a non-single-crystal semiconductor film 14 including a plurality of crystal grains. The support substrate 12 supports the non-single-crystal semiconductor film 14. The active device 10 is a thin-film transistor that is used as a structural element of a pixel switching device or a video processing circuit in the active matrix type liquid crystal display apparatus. The active device 10 includes a part of the non-single-crystal semiconductor film 14 as a channel region. The support substrate 12 may be formed of, for instance, a semiconductor substrate including silicon or other semiconductor, or an insulative substrate made of Corning 1737 glass, fused silica, sapphire, plastic, polyimide, etc. In this embodiment, a Corning 1737 glass substrate is used for the support substrate 12. The semiconductor film 14 may be formed of a layer containing semiconductor such as silicon (Si) or silicon germanium (SiGe). In this embodiment, the non-single-crystal semiconductor film 14 is formed of silicon.

As is shown in FIG. 2, the active device 10 includes a gate insulation film 16 covering the non-single-crystal semiconductor film 14, and a gate electrode layer 18 disposed on the gate insulation film 16. The semiconductor film 14 is formed on an underlying insulation layer 20 covering the support substrate 12. The semiconductor film 14, however, may be formed directly on the support substrate 12 without the intervention of the underlying insulation layer 20.

The semiconductor film 14 includes a channel region 22 located below the gate electrode layer 18, and a source region 24 and a drain region 26 disposed on both sides of the channel region 22 and containing p-type or n-type impurities. In this embodiment, the source region 24 and drain region 26 contain n-type impurities. The gate insulation film 16 is formed of an oxide such as silicon dioxide (SiO₂). The gate insulation film 16 electrically insulates the gate electrode layer 18 from the channel region 22, thus making the thin-film transistor function as a field-effect transistor. The channel region 22 is a region where carriers such as electrons or holes are moved between the source region 24 and drain region 26. The motion of carriers is controlled by an electric field that is produced in accordance with a gate voltage applied to the gate electrode layer 18.

The underlying insulation film 20 functions to prevent impurities in the support substrate 12 such as the glass substrate from moving to the semiconductor film 14. In this embodiment, the underlying insulation layer 20 is formed of SiO₂. The underlying insulation layer 20 may be formed of an oxide such as silicon dioxide (SiO₂), silicon nitride (SiN), a double-layer structure of silicon nitride and silicon dioxide (SiN/SiO₂), alumina or mica. If the underlying insulation layer 20 is the double-layer structure of an SiN layer covering the support substrate 12 and an SiO₂ layer covering the SiN layer, the effect of preventing motion of impurities is enhanced.

The non-single-crystal semiconductor film 14 has an oxide concentration not higher than 1×10¹⁸ atoms/cm³, and a carbon concentration not higher than 1×10¹⁸ atoms/cm³. In other words, each of the number of carbon atoms and the number of oxygen atoms is 1×10¹⁸ or less per cm³. In the case where at least the channel region 22 of the semiconductor film 14 has these oxygen concentration and carbon concentration, micro-defects occurring in the crystalline structure of the channel region 22 due to these elements can be reduced to a very small value of about 1×10⁶/cm⁻³, which is practically tolerable. Thereby, the carriers in the channel region 22 can move at high speed without being considerably hindered by micro-defects. Therefore, the thin-film transistor can have good electrical characteristics for performing high-speed switching operations.

Preferably, the non-single-crystal semiconductor film 14 should have an oxide concentration not higher than 5×10¹⁷ atoms/cm³, and a carbon concentration not higher than 5×10¹⁷ atoms/cm³. In other words, each of the number of carbon atoms and the number of oxygen atoms is 5×10¹⁷ or less per cm³. In the case where at least the channel region 22 of the semiconductor film 14 has these oxygen concentration and carbon concentration, the quality of the channel region 22 is enhanced.

Besides, it is preferable that the non-single-crystal semiconductor film 14 have a metal element concentration not higher than 1×10¹⁷ atoms/cm³. In other words, the number of metal atoms is 1×10¹⁷ or less per cm³. In the case where at least the channel region 22 of the semiconductor film 14 has this metal element concentration, generation of a metal oxide that leads to a decrease in resistivity of the semiconductor film 14 is suppressed. If the number of metal atoms is 5×10¹⁶ or less per cm³, generation of a metal oxide is further suppressed and the resistivity can be reduced to a practically tolerable value.

In the non-single-crystal semiconductor film 14, a plurality of crystal grains have the same growth direction. This growth direction coincides with the direction of arrangement of the source region 24 and drain region 26. In other words, the source region 24, channel region 22 and drain region 26 are arranged in the growth direction of the crystal grains. Further, in this growth direction, the crystal grains have a grain size greater than the length of the channel region, and the channel region 22 is located within a single crystal grain. In this case, no crystal grain boundary is present in the channel region 22, and it becomes possible to eliminate hindrance to motion of carriers due to crystal grain boundaries within the channel region 22. To reduce each of the number of oxygen atoms and the number of oxygen atoms to 1×10¹⁸ or less per cm³ contributes greatly to a decrease in number of crystal-structural micro-defects. Practically, if the crystal grain size is set at a ¼ or more of the length of the channel region 22, for example, if the crystal grain size is set at a 0.5 μm or more when the channel region 22 has a length of 2 μm, the number of crystal grain boundaries that the carriers encounter within the channel region 22 can relatively be reduced, and the advantageous effect of eliminating impurity elements is confirmed.

The length (lithographical gate length) of the channel region 22 in the direction of arrangement of the source region 24 and drain region 26 is greater than the length (effective gate length) of the gate electrode layer 18 in this direction of arrangement. The aforementioned effect can be obtained if there is no crystal grain boundary and each of the number of oxygen atoms and the number of oxygen atoms is 1×10¹⁸ or less per cm³ in the range of at least the effective gate length. If these conditions are established in the range of the lithographical gate length, the effect is further enhanced.

As described above, in order to decrease the number of crystal-structural micro-defects in the channel region 22, it is effective to set each of the number of oxygen atoms and the number of oxygen atoms in the channel region 22 at a value not higher than 1×10¹⁸ per cm³. The reasons for this are explained in greater detail.

1. Correlation Between Oxygen and Carbon and Stacking Fault Density

As regards a plurality of samples, a correlation was examined between the oxygen concentration (atoms/cm³), which is the number of oxygen atoms per cm³, the carbon concentration (atoms/cm³), which is the number of carbon atoms per cm³, and the stacking fault density (cm⁻³) that is the amount of crystal-structural defects per cm³ of the semiconductor film 14.

Each sample was prepared as follows. Use was made of equipment that can maintain contaminants such as oxygen and carbon at low concentrations with respect to only experimentally fabricated samples. A support substrate 12 made of Corning #1737 glass was prepared. An underlying insulation layer 20 was formed on the support substrate 12. The underlying insulation layer 20 has a double-layer structure wherein a silicon nitride (SiNx) layer 50 nm thick and a silicon oxide (SiOx) layer 100 nm thick are stacked in the named order. An amorphous silicon film with a thickness of 200 nm was formed on the underlying insulation layer 20.

As regards the samples, the concentrations of the elements, i.e. oxygen, carbon and nickel, in the amorphous silicon film were measured by a secondary ion mass spectroscopy (SIMS) apparatus manufactured by CAMECA of Courbevoie, France. This apparatus adopts a secondary ion mass spectroscopy technique. In this technique, an ion beam using ions such as O⁺, Cs⁺, etc., as irradiation ions is applied to a layer from above. Secondary ions produced from atoms or molecules in the layer, which are emitted from the surface of the layer by a sputtering phenomenon, are detected. Thus, mass spectroscopy of elements is performed. The ion beam is successively applied, and etching of the layer by the sputtering phenomenon is continued to carry out the mass spectroscopy in the depth direction of the layer.

The concentrations of oxygen, carbon and nickel in the amorphous silicon film were measured as initial concentrations immediately after the formation of the amorphous silicon film. The measured result showed that the initial concentration of oxygen was 2×10¹⁷ atoms/cm³ or less, the initial concentration of carbon was 3×10¹⁶ atoms/cm³ or less, and the initial concentration of nickel was a value less than the lower detection limit of spectroscopy by the CAMECA SIMS apparatus.

After confirming the initial concentrations of oxygen, carbon and nickel, oxygen and carbon were implanted in the amorphous silicon films of the respective samples by ion implantation. As is shown in FIG. 3, 15 samples were obtained by combining three values of carbon dose and five values of oxygen dose. Acceleration energy is the energy for driving atoms of a dopant, thereby implanting them into the amorphous silicon film. The acceleration energy for carbon is 100 keV, and the acceleration energy for oxygen is 130 keV. The dose is expressed by the number of atoms of dopant, which pass through a unit area of 1 cm².

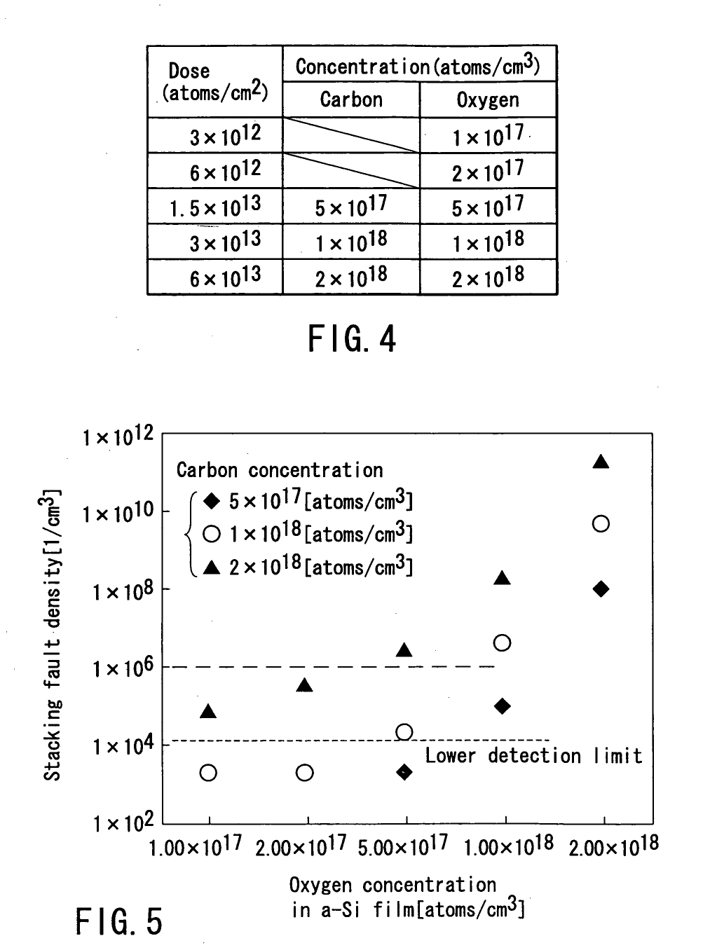

FIG. 4 shows the carbon and oxygen concentrations obtained in the amorphous silicon films, relative to the doses indicated in FIG. 3. These carbon and oxygen concentrations are average numbers of carbon atoms and oxygen atoms that are present per unit volume of 1 cm³. An insulation layer (hereinafter referred to as “cap layer”) of silicon oxide (SiOx) having a thickness of 300 nm was formed on the amorphous silicon film. The amorphous silicon film was then subjected to a laser annealing process. In the laser annealing process, a KrF excimer laser beam was applied to the amorphous silicon film through a phase shifter that phase-shifts at least a part of the laser beam. Thus, the amorphous silicon film was melted and recrystallized into a polysilicon film. The conditions for the laser irradiation were set such that the number of times of irradiation was one and the radiation fluence was 560 mJ/cm² on average in the radiation plane. The cap layer prevents an ablation phenomenon in which silicon is removed from a part of the amorphous silicon film due to evaporation, etc., as a result of irradiation of the KrF excimer laser beam.

After the polysilicon film was obtained by the melting/recrystallization using the laser annealing process, micro-defects in the crystalline structure of the polysilicon film were inspected by taking an X-ray diffraction image of the polysilicon film by X-ray diffraction analysis and analyzing the peak shift of the diffraction image.

FIG. 5 shows the oxygen concentration dependence of the stacking fault density in the polysilicon film, taking the carbon concentrations shown in FIG. 4 as parameters. In FIG. 5, a lower detection limit indicated by a broken line was determined in consideration of the reproducibility, that is, reliability, of measured values in the measurement of the stacking fault density. In the analysis of the peak shift of the diffraction image by the modern X-ray diffraction analysis apparatus, an analysis result depends on the analysis performance of the analysis apparatus or the analyzer's interpretation in a case where the stacking fault density is very low. The analysis result varies depending on the performance or interpretation.

As is understood from FIG. 5, if each of the carbon concentration and the oxygen concentration is 1×10¹⁸ atoms/cm³, the stacking fault density falls to a value that is slightly higher than the lower detection limit. If each of the carbon concentration and the oxygen concentration is 5×10¹⁷ atoms/cm³, the stacking fault density falls to a value that is lower than the lower detection limit.

2. Correlation Between Oxygen, Carbon and Metal Element, and Stacking Fault Density

A description is given of the case where not only oxygen and carbon but also nickel (Ni), as a metal element, is implanted in the samples of amorphous silicon films for which the initial concentrations of oxygen, carbon and nickel were confirmed as mentioned above. Since nickel has a large atomic mass of about 59, it is difficult to adequately implant nickel in the amorphous silicon film through a cap layer present on the amorphous silicon film. Thus, after the formation of the amorphous silicon film, nickel was directly implanted in the amorphous silicon film without the intervention of a cap layer, and oxygen and carbon were implanted in the amorphous silicon film through a cap layer formed after the implantation of the nickel.

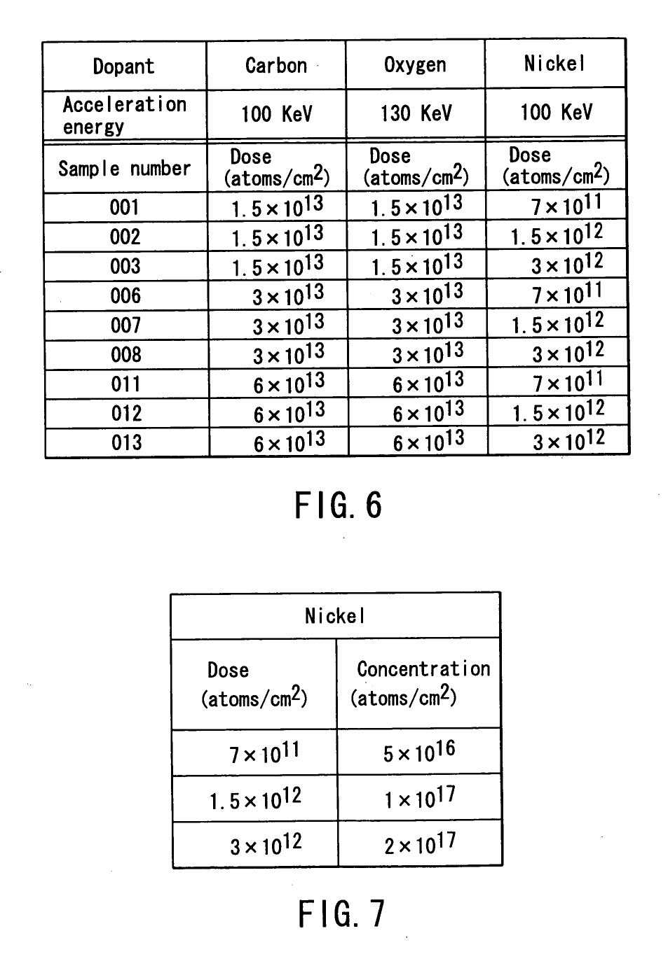

As is shown in FIG. 6, nine samples were obtained by combining three values of carbon dose, three values of oxygen dose and three values of nickel dose. FIG. 7 shows the nickel concentration obtained in the amorphous silicon films, relative to the nickel doses indicated in FIG. 6. The nickel concentration is an average number of nickel atoms that are present per unit volume of 1 cm³. After the formation of the samples, the amorphous silicon films of the respective samples were subjected to a laser annealing process. In the laser annealing process, a. KrF excimer laser beam was applied to the amorphous silicon films through the phase shifter, as mentioned above. Thus, the amorphous silicon films were melted and recrystallized into polysilicon films.

After the polysilicon films were obtained by the melting/recrystallization using the laser annealing process, micro-defects in the crystalline structure of each polysilicon film were inspected by taking an X-ray diffraction image of the polysilicon film by X-ray diffraction analysis and analyzing the peak shift of the diffraction image.

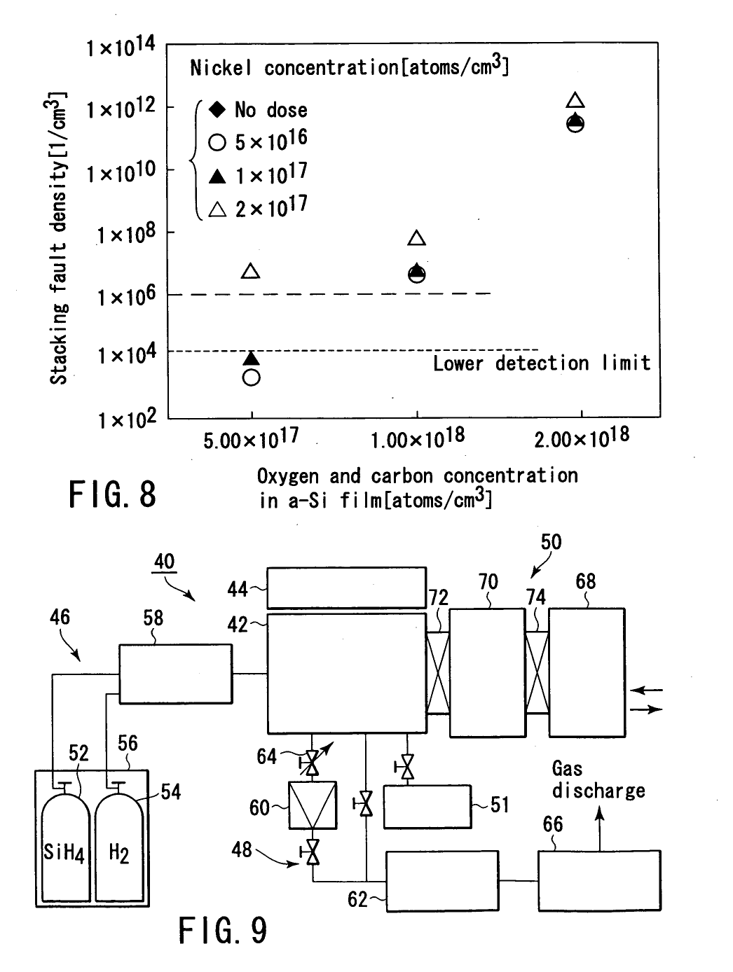

FIG. 8 shows the carbon and oxygen concentration dependence of the stacking fault density in the polysilicon film, taking the nickel concentration shown in FIG. 7 as parameters. In FIG. 8, a lower detection limit indicated by a broken line was determined in consideration of the reproducibility, that is, reliability, of measured values in the measurement of the stacking fault density, as with the case of the broken line in FIG. 5.

As is understood from FIG. 8, if each of the carbon concentration and the oxygen concentration is 1×10¹⁸ atoms/cm³ and the nickel concentration is 1×10¹⁷ atoms/cm³, the stacking fault density falls to a value that is slightly higher than the lower detection limit. If each of the carbon concentration and the oxygen concentration is 5×10¹⁷ atoms/cm³ and the nickel concentration is 1×10¹⁷ atoms/cm³, the stacking fault density falls to a value that is lower than the lower detection limit. Further, if the nickel concentration is 5×10¹⁶ atoms/cm³ or less, this increases the certainty that the stacking fault density falls to a value that is lower than the lower detection limit.

In the semiconductor device shown in FIG. 2, the support substrate 12 and non-single-crystal semiconductor film 14 constitute a major semiconductor structure to be used as a panel substrate component of the liquid crystal display apparatus. If mixture of impurities occurring in the keeping and transportation time is taken into account, it is preferable, in practice, to cover the non-single-crystal semiconductor film 14 with at least an insulation film such as the gate insulation film 16. This semiconductor structure is a half-finished product of the semiconductor device, and it does not need to include all of the components of the semiconductor device such as the gate electrode layer 18, source region 24 and drain region 26, as shown in FIG. 2. In this example, a half-finished product, wherein the non-single-crystal semiconductor film 14 includes the source region 24 and drain region 26 on both sides of the channel region 22 and no contact hole for exposing the non-single-crystal semiconductor film 14 is formed in the gate insulation film 16 by etching, is employed as the panel substrate component of the liquid crystal display apparatus.

FIG. 9 schematically shows a manufacturing apparatus for use in fabricating the semiconductor device shown in FIG. 2. The manufacturing apparatus comprises a plasma-enhanced chemical vapor deposition (PECVD) apparatus 40 shown in FIG. 9. The PECVD apparatus 40 includes a reactor chamber 42 that is an air-tight semiconductor film forming chamber, which accommodates the support substrate 12 to be subjected to a PECVD film-forming process; a plasma generation source 44 that generates a plasma to be used in PECVD; a material gas supply system 46 for supplying plasma-generation material gases into the reactor chamber 42; and an exhaust process system 48 for evacuating the reactor chamber 42.

A substrate conveyance system 50 is connected to the PECVD apparatus 40. The substrate conveyance system 50 functions to convey, with a predetermined degree of vacuum, the support substrate 12 into the reactor chamber 42 and to take it out of the reactor chamber 42.

A mass spectroscopy unit 51 for identifying gases within the reactor chamber 42 is connected to the reactor chamber 42. A quadrupole mass spectroscope (QMS), for instance, is used as the mass spectroscopy unit 51.

The material gas supply system 46 includes a material gas cylinder unit 56 having, e.g., a silane (SiH₄) gas cylinder 52 and a hydrogen (H₂) gas cylinder 54, and a mass flow controller 58. In the material gas supply system 46, the flow rate of each of silane gas and hydrogen gas is adjusted by the mass flow controller 58, and the flow-rate-adjusted silane gas and hydrogen gas are introduced into the reactor chamber 42.

The exhaust process system 48 includes, for example, a turbo molecular pump (TMP) 60 and a dry pump 62. The dry pump 62 is connected to the turbo molecular pump 60 and reactor chamber 42. The exhaust process system 48 shown in FIG. 9 further includes an automatic pressure controller (APC) 64 connected between the reactor chamber 42 and turbo molecular pump 60, and a gas cleaner 66 that is connected to the exhaust side of the dry pump 62 and cleans exhaust gas to prevent environmental pollution.

The substrate conveyance system 50 includes a load chamber 68 for conveying substrates, and a robot chamber 70 for auto-sorting. The load chamber 68 has both a function of selecting a desired support substrate 12 from within a substrate keeping unit (not shown) and conveying it to the robot chamber 70, and a function of conveying the desired support substrate 12 from the robot chamber 70 to the substrate keeping unit. The robot chamber 70 sorts the support substrate 12 conveyed from the load chamber 68 to a predetermined substrate processing apparatus. In FIG. 9, only the PECVD apparatus is shown as the substrate processing apparatus.

It is necessary that gas within the robot chamber 70 be prevented from flowing into the reactor chamber 42 when a door 72 between the reactor chamber 42 and robot chamber 70 is opened. For this purpose, the robot chamber 70 is evacuated by an exhaust unit (not shown) and kept at a negative pressure, relative to the inside of the reactor chamber 42. Thus, the degree of vacuum within the robot chamber 70 is set to be higher than that of vacuum within the reactor chamber 42.

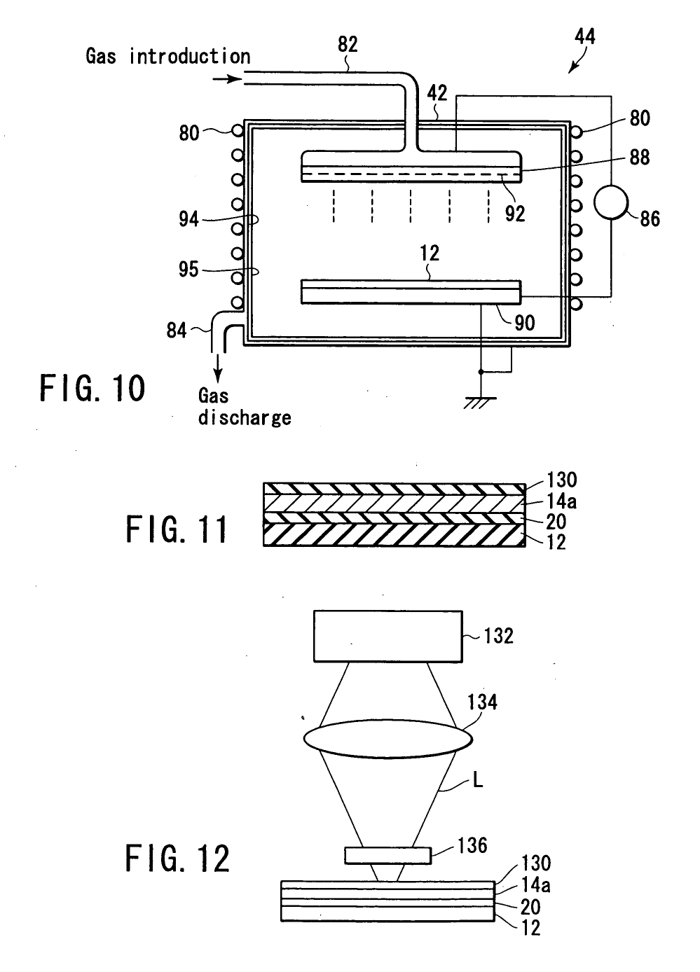

As is shown in FIG. 10, a heater 80 is wound, for example, in a coiled fashion, around the reactor chamber 42. The heater 80 is used to elevate the temperature within the reactor chamber 42,. A gas introduction conduit 82 is connected to the mass flow controller 58. A gas discharge conduit 84 is connected to the turbo molecular pump 60 via the automatic pressure controller 64. A gas exhaust conduit extending between the turbo molecular pump 60 and dry pump 62 is shown in FIG. 9 and thus omitted in FIG. 10.

The plasma generation source 44, as shown in FIG. 10, includes a radio-frequency (RF) generation unit 86, and an upper electrode 88 and a lower electrode 90 that are electrically connected to the RF generation unit 86. The lower electrode 90 and air-tight reactor chamber 42 are grounded. The upper electrode 88 has a mesh 92 with a plurality of openings. The upper electrode 88 is air-tightly connected to a flared part of the gas introduction conduit 82. The upper electrode 88 introduces a material gas G from the gas introduction conduit 82 into the reactor chamber 42 via the mesh 92. The lower electrode 92 supports the support substrate 12 that will undergo a film-formation process. In order to adjust the inter-electrode distance between the upper electrode 88 and lower electrode 90, the lower electrode 90 is configured to be vertically movable (in FIG. 10) by a drive mechanism (not shown).

The manufacturing method for the semiconductor device shown in FIG. 2 will now be described. In fabricating the semiconductor-device, an outgas process is performed to remove a gas mixing in a chamber inner wall 94 of the reactor chamber 42. In the outgas process, a baking process for the chamber inner wall 94 and an exhaust process for the reactor chamber 42 are carried out in parallel. The baking process is effected by heating the chamber inner wall 94 by means of the heater 80. In the baking process, the chamber inner wall 94 is heated up to a fixed temperature of, e.g., about 120° C. In addition, further heating is conducted to keep the fixed temperature for a predetermined time period of, e.g., several hours. The exhaust process is effected by continuously exhausting a gas, which has been produced from the chamber inner wall 94 in the baking process, from the reactor chamber 42 by the exhaust process system 48.

Subsequently, the chamber inner wall 94 is cleaned by delivering a fluorine based gas, such as fluorine trinitride gas, from a cylinder (not shown) to the reactor chamber 42 and etching the surface of the chamber inner wall 94 with the fluorine-based gas (“inner wall cleaning process”). Then, for example, an amorphous semiconductor film 95 with a thickness of 50 nm to 1000 nm is formed to cover the surface of the chamber inner wall 94 (“inner wall coating process”). This semiconductor film 95 is made of the same material as the semiconductor film 14 of the semiconductor device and functions to prevent fluorine, which has mixed in the chamber inner wall 94 during the surface etching process, from being released from the chamber inner wall 94 into the space within the reactor chamber 42.

The support substrate 12 is placed in the reactor chamber 42 after the above-described inner wall cleaning process and inner wall coating process. In the case of using the underlying insulation layer 20, the underlying insulation layer 20 is formed in advance on the support substrate 12 by plasma-enhanced chemical vapor deposition (PECVD). In a case where the underlying insulation layer 20 is, e.g., an SiO₂ layer, this SiO₂ layer is formed using a gas cylinder unit which includes a silane (SiH₄) gas cylinder, a nitrogen oxide (N₂O) gas cylinder and a nitrogen (N₂) gas cylinder, a gas cylinder unit which includes a tetra-ethyl ortho-silicate (TEOS) gas cylinder and an oxygen (O₂) gas cylinder, or the like. The support substrate 12, on which the underlying insulation layer 20 has been formed, is thus placed-in the reactor chamber 42.

In the case of a CVD apparatus for mass production, the inner wall cleaning process needs to be performed in a vacuum, taking into account the environment of use and the frequency of use. With repetition of the inner wall coating process, the thickness of the semiconductor film 95 increases cumulatively. It is thus preferable to periodically perform the inner wall cleaning process with a halogen-based gas or a fluoride gas, for example, each time the cumulative thickness of the semiconductor film 95 has reached, e.g., 10 μm, or in units of one lot.

After the support substrate 12 is placed in the reactor chamber 42, which has been subjected to the inner wall cleaning process and the inner wall coating process, as described above, an amorphous silicon film 14a shown in FIG. 11, for instance, is formed by PECVD as an amorphous semiconductor film supported on the support substrate 12.

The conditions for film formation in the case of forming the amorphous silicon film 14a by PECVD in the reactor chamber 42 shown in FIG. 9 are described. The mixing ratio (SiH₄/H₂) of silane gas to hydrogen gas introduced into the reactor chamber 42 is set at 1:4 based on a ratio in flow rate. The total gas pressure in the reactor chamber 42 is adjusted to be 150 Pa (1.1 Torr) by the APC 64. Thereby, the degree of vacuum within the reactor chamber 42 is kept to be constant. The rate of film formation is determined by plasma power and the flow rate of silane gas. The temperature of the support substrate 12 is kept at a constant value, e.g., 280° C., by a heater (not shown). The distance between the upper electrode 88 and lower electrode 90, or the distance between the upper electrode 88 and support substrate 12, is set at 15 mm at the time of the film formation process. Under these conditions, the amorphous silicon film 14a is formed.

Subsequently, as shown in FIG. 11, a cap layer 130, which is an insulation layer of silicon oxide with a thickness of 300 nm, is formed on the amorphous silicon film 14a. Then, the amorphous silicon film 14a is subjected to dehydrogenation treatment.

Thereafter, a laser annealing process for the amorphous silicon film 14a is performed using a laser beam applying unit shown in FIG. 12. In the laser beam applying unit, a KrF excimer layer beam L generated by a laser device 132 is applied to at least a region of the amorphous silicon film 14a through an optical system 134. The conditions for the irradiation of the KrF excimer laser beam L are set such that the number of times of irradiation was one and the radiation fluence is 560 mJ/cm² on average in the radiation plane. The KrF excimer laser beam L is applied to the amorphous silicon film 14a through a phase shifter 136 and the cap layer 130. Consequently, the amorphous silicon film 14a is melted and recrystallized into a polysilicon film. In this case, the cap layer 130 prevents the heat, which is produced within the amorphous silicon film 14a by the application of the excimer laser beam L, from being radiated out of the amorphous silicon layer 14a. Thereby, the excimer laser beam L is efficiently converted to thermal energy in the crystallization of the amorphous silicon film 14a.

The phase shifter 136 is formed of a transparent medium such as quartz. The phase shifter 136 has two regions with different thicknesses, which provide a phase difference of, e.g., 180°. In general, a step, that is, a difference t in thickness of two regions, which is necessary to obtain a phase difference of 180°, is expressed by

t=λ/2 (n−1) (1)

where λ is the wavelength of a laser beam, and n is the refractive index of the transparent medium with respect to the laser beam. In the case where quartz is used for the transparent medium, the difference t in thickness of two regions, which is required to obtain the phase difference of 180°, is 244 nm, since the wavelength of the KrF excimer laser beam is 248 nm and the refractive index of the quartz with respect to the KrF excimer laser beam is 1.508.

For example, in the case where the first region is made thinner than the second region, the phase shifter 136 can be obtained by selectively etching, in gas phase or liquid phase, the transparent medium in a range corresponding to the first region. Alternatively, the phase shifter 136 can be obtained by forming a light-transmissive film of SiO₂, etc., on the transparent medium by plasma CVD, low-pressure CVD, is etc., and patterning the light-transmissive film so as to leave a portion corresponding to the second region.

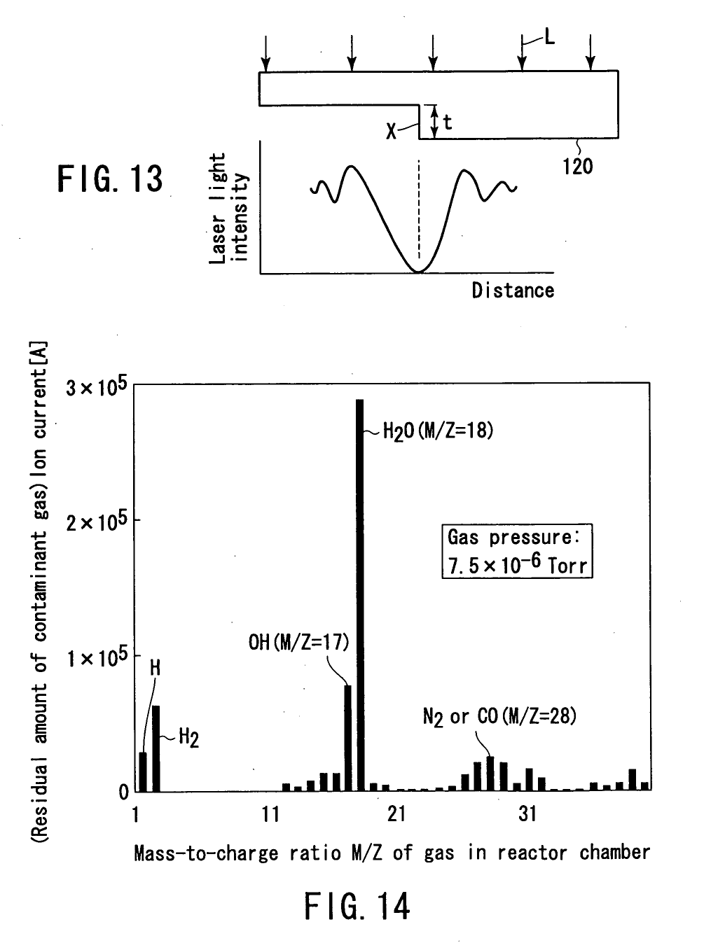

In the phase shifter 136, transmission light emerging from the second region travels with a time lag relative to transmission light emerging from the first region. The excimer laser beam L undergoes diffraction and interference due to the stepped portion formed at a boundary X between the first and second regions, and thus the beam L is spatially intensity-modulated. As a result, a light intensity distribution shown in FIG. 13 is obtained on the amorphous silicon film 14a. The light intensity takes a minimum value at a position along the boundary X. The amorphous silicon film 14a is set to have a temperature gradient corresponding to the light intensity distribution, and it is melted and recrystallized. A nucleus of a silicon crystal grain is generated at a part with a lowest temperature, and it grows horizontally toward a part with a higher temperature. In this embodiment, the position of generation of the nucleus is limited to the vicinity of a position in the amorphous silicon film, which is opposed to the boundary X and has a minimum light intensity, so as to grow a crystal grain to a larger size.

Following the laser annealing process, the cap layer 130 is removed by wet etching using, e.g., buffer hydrofluoric acid. A polysilicon film obtained by the melting/recrystallization of the amorphous silicon film 14a is patterned to leave a plurality of insular regions assigned to a plurality of active devices 10. The non-single-crystal semiconductor film 14 shown in FIG. 2 is a polysilicon film that is left as an insular region. A part of the non-single-crystal semiconductor film 14 constitutes the channel region 22 of the active device 10, i.e., the thin-film transistor.

Thereafter, an SiO₂ layer, for instance, is formed by plasma CVD as a gate insulation film 16 that covers the non-single-crystal semiconductor film 14. A gate electrode layer 18 is then formed on the gate insulation film 16 so as to be opposed to that part of the non-single-crystal semiconductor film 14, which becomes the channel region 22. The gate electrode layer 18 serves as a mask for implanting n-type or p-type impurities into the non-single-crystal semiconductor film 14. The n-type or p-type impurities are implanted through the gate insulation film 16 in regions on both sides of the gate electrode layer 18, thereby forming a source region 24 and a drain region 26 in parts of the semiconductor film 14. Thus, under the gate electrode layer 18, the channel region 22 is disposed between the source region 24 and drain region 26. A half-finished product of the semiconductor device is obtained at this stage.

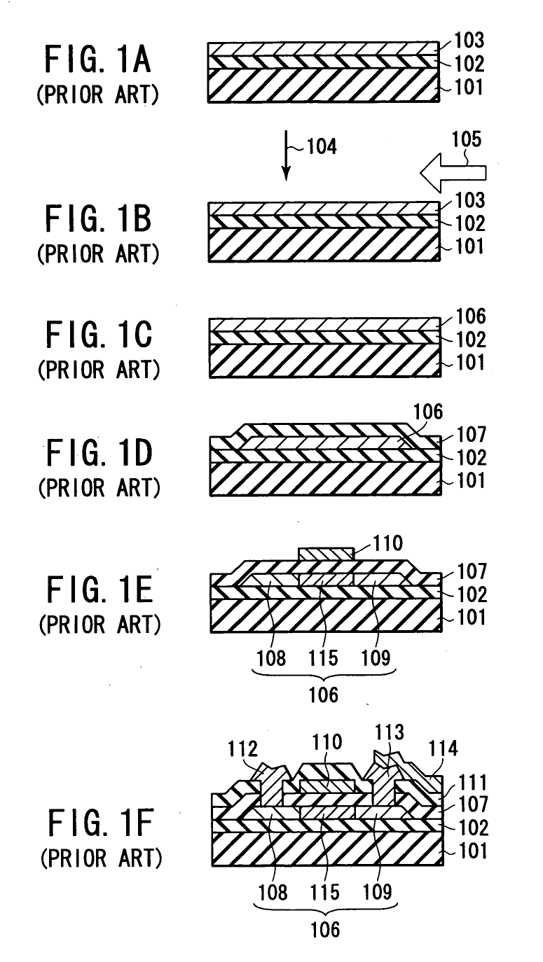

In order to complete the active device 10 in the half-finished product of the semiconductor device, an interlayer insulation film is formed like the interlayer insulation film 111 shown in FIG. 1F, and the impurities in the source region 24 and drain region 26 are activated by heat treatment. A pair of contact holes, like the contact-holes shown in FIG. 1F, are formed in the gate insulation film 16 and the interlayer insulation film. The contact holes partially expose the source region 24 and drain region 26. Then, a source electrode layer and a drain electrode layer are formed like the source electrode layer 112 and drain electrode layer 113 shown in FIG. 1F. The source electrode layer and drain electrode layer are put in electrical contact with the source region 24 and drain region 26 via the contact holes. Further, a metal wiring layer for transmitting electric signals is formed like the metal wiring layer 114 shown in FIG. 1F. The active device 10 is thus completed as a thin-film transistor. In the thin-film transistor, an electric current flows in the channel region 22 between the source region 24 and drain region 26 in accordance with a gate voltage applied to the gate electrode layer 18.

In the above-described outgas process, the chamber inner wall 94 is baked at 120° C. If the baking is performed in a temperature range of 80 to 150° C., impurity elements included in the chamber inner wall 94 are isolated or released. Further, the impurity elements are exhausted from the reactor chamber 42 by the exhaust process system 48. This prevents formation of the amorphous silicon film 14a that contains impurity elements separated from the chamber inner wall 94. Therefore, good crystallinity is obtained when the amorphous silicon film 14a is melted and recrystallized.

Next, residual gases in the reactor chamber 42 are described.

FIG. 14 shows a mass spectrum for identifying residual gases within the reactor chamber 42. This mass spectrum is a result of a mass spectroscopy that was conducted by the mass spectroscopy unit 51 shown in FIG. 9 with respect to the residual gases in the reactor chamber. The mass spectroscopy unit 51 that was used is a quadrupole mass spectroscope (QMS). In FIG. 14, an ion current (A), which is obtained from the mass spectroscopy unit 51 as a residual amount of contaminant gas, is indicated relative to the ratio M/Z between a mass corresponding to a gas mass unit and a charge number. M/Z=1 corresponds to H (hydrogen). M/Z=2 corresponds to H₂. M/Z=17 corresponds to OH. M/Z=18 corresponds to H₂O. M/Z=28 and ratios thereabout correspond to N₂ or CO.

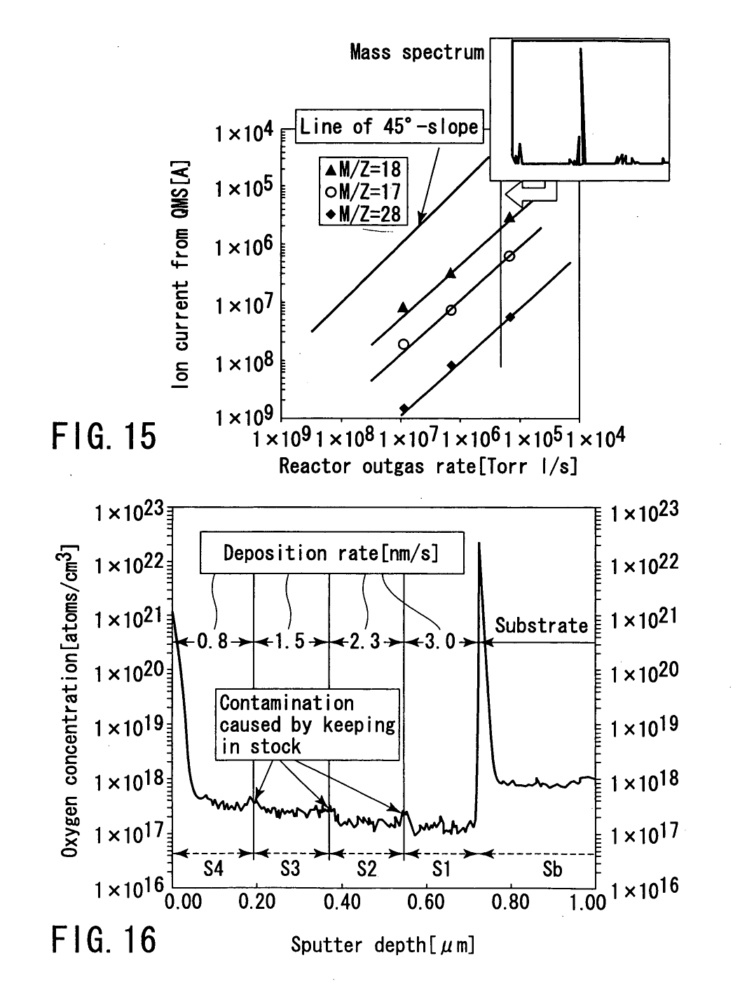

FIG. 15 shows a result of measurement of an ion current (A) of major residual gases within the reactor chamber 42 in relation to a reactor outgas rate (Torr l/s). Referring to FIG. 14, M/Z=17, M/Z=18 and M/Z=28 correspond to major residual gases. In FIG. 15, a black triangular mark indicates a measurement result relating to M/Z=18. A white circular mark indicates a measurement result relating to M/Z=17. A black diamond mark indicates a measurement result relating to M/Z=28. As is understood by referring to a straight line with an angle of 45° that is added to FIG. 15, the magnitude of the ion current linearly decreases as the outgas rate in the reactor chamber 42 increases. As regards H₂O (mass unit 17 or 18), oxygen is regarded as an impurity element that becomes a contaminant. As regards N₂ (mass unit 28), nitrogen is considered to be an impurity element that becomes a contaminant. Concerning CO or other hydrocarbons (mass units 28 and 12-16), carbon is regarded as an impurity element that becomes a contaminant. It is thus understood that in the formation of the silicon film 14a, a partial pressure on these impurity elements is proportional to the outgas rate from the reactor chamber 42.

FIG. 16 shows a profile of oxygen concentrations in the depth direction, which were measured with respect to samples of silicon films (to be used as semiconductor film 14 in FIG. 2) deposited on a substrate Sb at four different deposition rates. An SiO₂ layer is provided as an underlying insulation layer on the upper surface of the substrate Sb. In FIG. 16, S1 denotes a silicon film formed at a film formation rate of 3.0 nm/s, S2 denotes a silicon film formed at a film formation rate of 2.3 nm/s, S3 denotes a silicon film formed at a film formation rate of 1.5 nm/s, and S4 denotes a silicon film formed at a film formation rate of 0.8 nm/s. The silicon films S1, S2, S3 and S4 were deposited on the substrate Sb in the named order. These film formation rates were altered by adjustment of plasma power. The oxygen concentrations were measured while the silicon films S1, S2, S3 and S4 were being subjected to sputter etching. Referring to FIG. 16, it is understood that the oxygen concentration decreases as the film formation rate increases. Specifically, the oxygen concentration decreases in the order of silicon films S4, S3, S2 and S1. The silicon film S1 takes a minimum value of about 1.4×10¹⁷ atoms/cm³. Although the oxygen concentration profile has a high peak in the vicinity of the boundary between the substrate Sb and silicon film S1, this peak occurred due to oxygen in the SiO₂ layer of the substrate Sb.

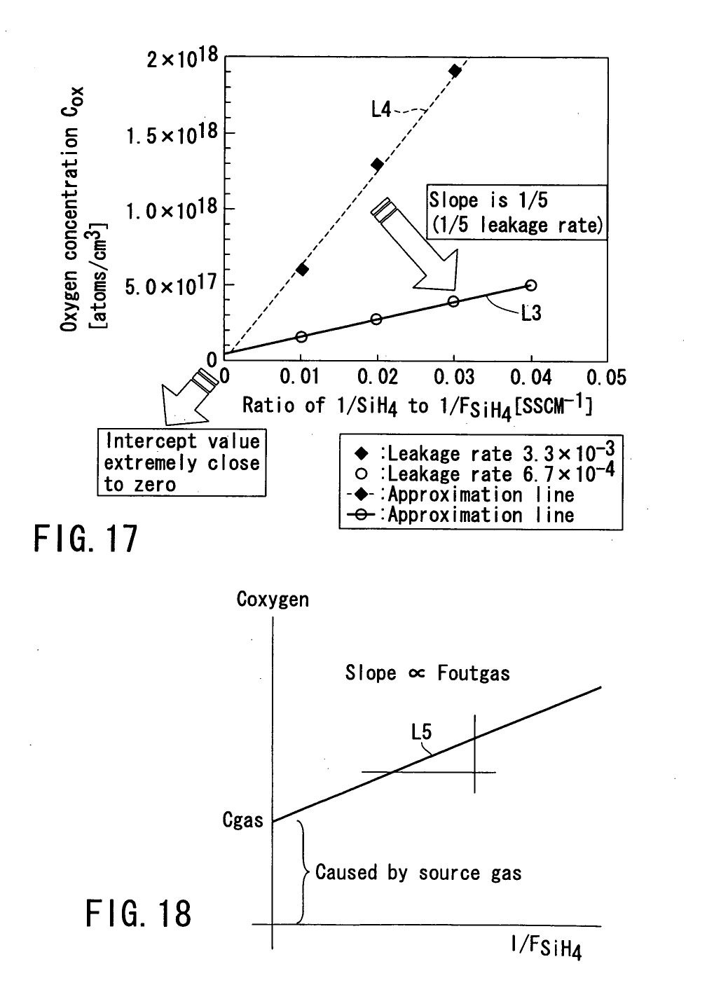

FIG. 17 demonstrates that the relationship between the concentration of silane gas introduced as a material gas into the reactor chamber 42 and the oxygen concentration in the silicon film depends on the leakage rate of the material gas. The material gas concentration is expressed by a ratio of 1/SiH₄ to 1/FsiH₄ (SCCM⁻¹) of silane gas. FsiH₄ is a value of flow rate of silane gas. A straight line L3 indicates a relationship obtained when the outgas process and inner wall cleaning process were performed (leakage rate=6.7×10⁻⁴). A straight line L4 indicates a relationship obtained when the outgas process and inner wall cleaning process were not performed (leakage rate=3.3×10⁻³). As is understood from FIG. 17, the degree of inclination of straight line L3 is ⅕ of that of straight line L4. That is, the degree of inclination was reduced to ⅕ by decreasing the leakage rate to ⅕. The oxygen concentration becomes lower when the outgas process and inner wall cleaning process were performed than when the outgas process and inner wall cleaning process were not performed. Noticeably, intercept values of the two straight lines L3 and L4 are very close.

The oxygen concentration shown in FIG. 17 is explained in greater detail, using the formula

$${C}_{oxygen} ∼ \frac{{F}_{outgas}}{{F}_{{SiH}_{4}}} \times {N}_{Si} + {C}_{gas} \qquad ( 2 )$$

where C_{oxygen} is the oxygen concentration in the silicon film, C_{gas} is the oxygen concentration in the material gas (e.g., silane gas), F_{outgas} is the flow rate of contaminant as a gas produced by outgassing, F_{SiH4} is the flow rate of silane gas, and N_{Si} is the number (density) of silicon atoms per unit volume in the silicon film. C_{gas} is constant with respect to the material gas (e.g., silane gas). In formula (2), (F_{outgas}/F_{SiH4})×N_{Si}≡C_{outgas} designates the concentration of oxygen that has occurred by outgassing, and it is proportional to 1/F_{SiH4}.

FIG. 18 demonstrates that the proportional relationship between the inverse number of flow rate of silane gas introduced as material gas to the reactor chamber 42 and the oxygen concentration in the silicon film is defined by a characteristic straight line with an inclination proportional to the flow rate of contaminant gas produced by outgassing. In FIG. 18, a straight line L5 indicates the proportional relationship between the inverse number of flow rate F_{SiH4} of silane gas and the oxygen concentration C_{oxygen} in the silicon film. The inclination of the straight line L5 is proportional to the flow rate F_{outgas} of contaminant gas and satisfies formula (2).

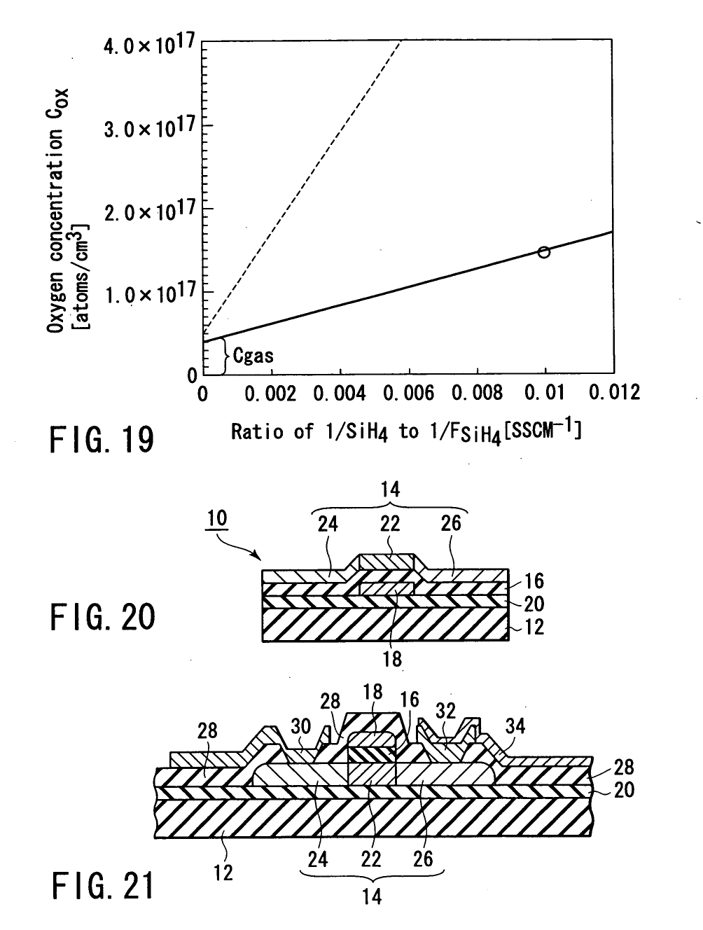

FIG. 19 shows, in enlarged scale, a range encircled in FIG. 17. The oxygen concentration C_{gas} in the material gas (e.g., silane gas) substantially falls within a range of 4×10¹⁶ atoms/cm³ to 5×10¹⁶ atoms/cm³ (corresponding approximately to 1 ppm). The difference between the oxygen concentration C_{gas} in the material gas (e.g., silane gas) and the oxygen concentration C_{bomb} due to the material gas cylinder corresponds to impurities from the material gas supply system. The oxygen concentration C_{bomb} due to the material gas cylinder is less than 0.5 ppm.

In the above-described semiconductor device, each of the number of oxygen atoms and the number of carbon atoms in the channel region 22 is 1×10¹⁸ or less per cm³. Otherwise, the number of oxygen atoms, the number of carbon atoms and the number of metal atoms in the channel region 22 are 1×10¹⁸ or less per cm³, 1×10¹⁸ or less per cm³, and 1×10¹⁷ or less per cm³, respectively. These numbers are numerical values at the time of completion of fabrication of the semiconductor device. Thus, when the semiconductor device is to be fabricated, it is possible that a non-single-crystal (amorphous or polycrystalline) having, for example, the numbers of oxygen atoms and carbon atoms higher than the aforementioned values is formed in advance. In such a case, excess atoms are removed by, e.g., a low-temperature gettering process in a subsequent fabrication step, thereby adjusting the numbers of oxygen atoms and carbon atoms to the aforementioned values or less.

The manufacturing apparatus shown in FIG. 9 is, for instance, a multi-chamber type plasma CVD apparatus with load locks. The chamber inner wall 94 contains no SUS metal materials including iron, nickel, cobalt, etc., which may be released to the reactor chamber 42 and mix in the semiconductor film. Instead, the chamber inner wall 94 is formed of an aluminum-containing metal material. Thereby, when cleaning using a fluorine-based gas is performed, aluminum that is a metal component of the inner wall 94 is combined with fluorine, and a fluorine compound is produced. When aluminum and fluorine are included in the inner wall 94 as a fluorine compound, it is possible to prevent the aluminum and fluorine from being released from the chamber inner wall 94 to the inside space of the reactor chamber 42 and mixing as contaminant into the semiconductor film in the making.

It is preferable that the material of the inner wall 94 be an aluminum-magnesium-based metal material (a metal material with a number on the order of A5000 [JIS], for instance, a A5052-series metal material). More preferably, the material of the inner wall 94 should be an aluminum-magnesium-silicon-based metal material (a metal material with a number on the order of A6000 [JIS]) or an aluminum-copper-based material (a metal material with a number on the order of A2000 [JIS], for instance, a A2219-series metal material).

It is preferable that the surface of the inner wall 94 of the reactor chamber 42 have a roughness of 6.4 μm or less. This provides the inner wall 94 with a smooth surface capable of suppressing adhesion of impurity elements, and maintains the clean condition of the inner wall 94 for a long time.

Besides, a layer of magnesium aluminum fluoride formed by combination with fluorine, for instance, may be provided on the surface of the inner wall 94. Further, the surface of the inner wall 94 may be coated with an amorphous semiconductor film having a thickness of 50 to 1000 nm. This also prevents fluorine atoms included in the inner wall 94 from being released to the inside space of the reactor chamber 42 and mixing as contaminant in the semiconductor film in the making.

The reaction chamber 42 is shielded from the outside by means of a fluoro-rubber O-ring having heat resistance. Thereby, damage to the O-ring due to heat in the baking process for the inner wall 94 can be reduced. Alternatively, this O-ring may be replaced with, e.g., two stacked O-rings of fluoro-rubber, which have heat resistance and have different diameters. The reactor chamber 42 may be shielded from the outside by these two O-rings. This ensures-shielding of the reactor chamber 42 from the outside. Moreover, damage to each O-ring can be reduced. Additionally, the reactor chamber 42 may include an exhaust unit for removing a contaminant gas from a gap between the two O-rings.

The semiconductor device shown in FIG. 2 has the following stacked structure. The support substrate 12 is an underlayer of the underlying insulation layer 20. The underlying insulation layer 20 is an underlayer of the non-single-crystal semiconductor film 14. The non-single-crystal semiconductor film 14 is an underlayer of the gate insulation film 16. The gate insulation film 16 is an underlayer of the gate electrode layer 18. This stacked structure may be modified, for example, as shown in FIG. 20.

FIG. 20 shows a first modification of the semiconductor device shown in FIG. 2. This modification has the following stacked structure. The support substrate 12 is an underlayer of the underlying insulation layer 20. The underlying insulation layer 20 is an underlayer of the gate electrode layer 18. The gate insulation layer 18 is an underlayer of the gate insulation film 16, and the gate insulation film 16 is an underlayer of the semiconductor film 14.

In the manufacture of the semiconductor device according to the first modification, after the underlying insulation layer 20 is formed the gate electrode layer 18 is formed and the gate insulation film 16 is formed to cover the gate electrode layer 18. The gate insulation film 16 extends over the underlying insulation layer 20.

Subsequently, an amorphous silicon film, for instance, is deposited by plasma CVD as an amorphous semiconductor film on the gate insulation film 16. The amorphous silicon film is formed using the PECVD apparatus 40 shown in FIG. 9. Prior to the formation of the amorphous silicon film, the inner wall 94 of the reactor chamber 42 is subjected to the outgas process and cleaned by the surface etching process using a fluorine-based gas. Further, the inner wall 94 is coated with the amorphous semiconductor film 95. The amorphous silicon film is formed in this reactor chamber 42. Next, the cap layer is formed on the amorphous silicon film, and the amorphous silicon film is subjected to dehydrogenation treatment. Then, the laser annealing process is conducted on the amorphous silicon film. In the laser annealing process, the KrF excimer laser beam, for instance, is applied to the amorphous silicon film through the phase shifter under the aforementioned irradiation conditions. Thereby, the amorphous silicon film is melted and recrystallized into a polysilicon film. The non-single-crystal silicon film 14 shown in FIG. 20 is the polysilicon film thus formed. Following this, the aforementioned cap layer is removed by, e.g., wet etching using buffer hydrofluoric acid.

In a subsequent step, a resist layer having substantially the same pattern size as the gate electrode layer 18 is formed on the channel region 22. Using the resist layer as a mask, n-type or p-type impurities are implanted in the semiconductor film 14. Thus, the source region 24 and drain region 26 are formed on both sides of the channel region 22 in the semiconductor film 14. In this case, the sizes of the source region 24 and drain region 26 can be adjusted by the pattern size of the resist layer. A semi-finished product of the semiconductor device shown in FIG. 20 is obtained at this stage.

Thereafter, the same process as with the semiconductor device shown in FIG. 2 is performed. An interlayer insulation film is formed so as to cover the semiconductor layer 14. The impurities in the source region 24 and drain region 26 are activated by heat treatment. A pair of contact holes are formed in the gate insulation film 16 and the interlayer insulation film. The contact holes partially expose the source region 24 and drain region 26. Then, a source electrode layer and a drain electrode layer are formed so as to be put in electrical contact with the source region 24 and drain region 26 via the contact holes. Further, a metal wiring layer for transmitting electric signals is formed. The active device 10 is thus completed as a thin-film transistor.

FIG. 21 shows a second modification of the semiconductor device shown in FIG. 2. The semiconductor device shown in FIG. 2 has such a structure that the gate insulation film 16 covers the non-single-crystal semiconductor film 14. Alternatively, as shown in FIG. 21, the gate insulation film 16 may cover only the channel region 22 of the semiconductor film 14. In this case, the gate electrode layer 18 is formed on the gate insulation film 16, and the interlayer insulation film 28 is formed so as to cover the gate electrode layer 18, source region 24 and drain region 26. A source electrode layer 30 and a drain electrode layer 32 are formed so as to be put in contact with the source region 24 and drain region 26 in a pair of contact holes formed in the interlayer insulation film 28. Further, a metal wiring layer 34 is formed so as to be connected to the drain electrode layer 32. The active device 10 is thus completed as a thin-film transistor.

In the semiconductor device shown in FIG. 2, the cap layer 130 is completely removed. Alternatively, the cap layer 130 may be etched so as to have the same thickness as the gate insulation film 16, and it may be used as the gate insulation film 16.

In the manufacture-of the semiconductor device shown in FIG. 2, the laser annealing process is carried out to melt and recrystallize the amorphous silicon film 14a that is the non-single-crystal semiconductor film. In the laser annealing process, the KrF excimer laser beam is applied to the amorphous silicon film 14a via the phase shifter 136. The excimer laser beam may be directly applied one or more times to the amorphous silicon film 14a for crystallization without the use of the phase shifter 136. In the scheme in which the phase shifter 136 is not used, the crystal grain cannot be grown to such a large size as is achieved by the scheme using the phase shifter 136. However, the fluence of the beam radiation is relatively small, compared to the scheme using the phase shifter 136. Hence, there is no need to form the cap layer 130.

The melting/recrystallization of the non-single-crystal semiconductor film such as amorphous silicon film 14a may be effected by a lamp annealing process using energy light other than the laser beam. In addition, the melting/recrystallization of the non-single-crystal semiconductor film may be effected not by a method of radiating energy light, but by a solid-state epitaxial growth in, e.g., a nitrogen atmosphere. In either case, it is desirable that the non-single-crystal semiconductor be melted and recrystallized for a heating time of 10 seconds or less at the heating place. More preferably, the heating-time should be one second or less. This can suppress contamination of the semiconductor film in the melted state.

In the present embodiment, as described above, the channel region 22 has an oxygen concentration and a carbon concentration, each of which is not higher than 1×10¹⁸ atoms/cm³. If at least the channel region 22 of the non-single-crystal semiconductor film 14 has such an oxygen concentration and a carbon concentration, micro-defects occurring in the crystalline structure of the channel region 22 due to these elements can be reduced to a very small value of about 1×10⁶/cm⁻³, which is practically tolerable. Thereby, the carriers can move through the channel region 22 at high speed without being considerably hindered by micro-defects. Therefore, the thin-film transistor can have good electrical characteristics for performing high-speed switching operations.

If at least the channel region 22 of the non-single-crystal semiconductor film 14 has an oxide concentration not higher than 5×10¹⁷ atoms/cm³, and a carbon concentration not higher than 5×10¹⁷ atoms/cm³, the quality of the channel region 22 is enhanced.

Besides, if the non-single-crystal semiconductor film 14 has a metal element concentration not higher than 1×10¹⁷ atoms/cm³, generation of a metal oxide that leads to a decrease in resistivity of the semiconductor film 14 is suppressed. If the number of metal atoms is 5×10¹⁶ or less per cm³, generation of a metal oxide is further suppressed and the resistivity can be reduced to a practically tolerable value.

In the non-single-crystal semiconductor film 14, the source region 24, channel region 22 and drain region 26 are arranged in the growth direction of the crystal grains. Further, in this growth direction, the channel region 22 is located within the single crystal grain that has a size not less than the length of the channel region 22. In this case, no crystal grain boundary is present in the channel region 22, and it becomes possible to eliminate hindrance to motion of carriers due to crystal grain boundaries within the channel region 22.

In the semiconductor device, if the inner wall 94 of the reactor chamber 42, which is the film forming chamber accommodating the support substrate 12, is formed of an aluminum-magnesium-based metal material, an aluminum-magnesium-silicon-based metal material or an aluminum-copper-based material, it is possible to prevent the metal elements of the material of the inner wall 94 from being released to the inside space of the reactor chamber 42 and mixing in the non-single-crystal semiconductor film 14. If the surface of the inner wall 94 has a roughness of 6.4 μm or less, the inner wall 94 can have a smooth surface capable of suppressing adhesion of impurity elements, and the clean condition of the inner wall 94 can be maintained for a long time.

Besides, the inner wall 94 of the reactor chamber 42 is subjected to surface etching treatment using a fluorine-based gas, and the surface of the inner wall 94 is coated with an amorphous semiconductor film 95 having a thickness of 50 to 1000 nm. Thereby, the contaminant elements are removed from the surface of the chamber inner wall 94 by the surface etching treatment, and the fluorine included in the inner wall 94 by the surface etching treatment is prevented from being released to the inside space of the reactor chamber 42. Therefore, the contaminant mixing in the non-single-crystal semiconductor film in the making can be reduced.

If the reaction chamber 42 is shielded from the outside by means of a fluoro-rubber O-ring having heat resistance, damage to the O-ring due to heat in the baking process for the inner wall 94 can be reduced. Alternatively, this O-ring may be replaced with, e.g., two stacked O-rings of fluoro-rubber, which have heat resistance and have different diameters. If the reactor chamber 42 is shielded from the outside by these two O-rings, the shielding of the reactor chamber 42 from the outside is ensured and damage to each O-ring can be reduced. Additionally, if the reactor chamber 42 includes an exhaust unit for removing a contaminant gas from a gap between the two O-rings, the adverse effect of the contaminant can be eliminated.

Additional advantages and modifications will readily occur to those skilled in the art. Therefore, the invention in its broader aspects is not limited to the specific details and representative embodiments shown and described herein. Accordingly, various modifications may be made without departing from the spirit or scope of the general inventive concept as defined by the appended claims and their equivalents.

What is claimed is:

1. A semiconductor structure comprising a non-single-crystal semiconductor film including a channel region for an active device, and a support substrate that supports the non-single-crystal semiconductor film, the channel region having an oxygen concentration not higher than 1×10¹⁸ atoms/cm³ and a carbon concentration not higher than 1×10¹⁸ atoms/cm³.

2. The semiconductor structure according to claim 1, wherein each of the oxygen concentration and the carbon concentration is not higher than 5×10¹⁷ atoms/cm³.

3. The semiconductor structure according to claim 1, wherein the channel region includes a metal element with a concentration not higher than 1×10¹⁷ atoms/cm³.

4. The semiconductor structure according to claim 3, wherein the concentration of the metal element is not higher than 5×10¹⁶ atoms/cm³.

5. A manufacturing method for a semiconductor structure having a non-single-crystal semiconductor film including a channel region for an active device, and a support substrate that supports the non-single-crystal semiconductor film, the method comprising subjecting an inner wall of a film-forming chamber to a surface etching process with a fluorine-based gas, coating the inner wall with an amorphous semiconductor film with a thickness of 50 to 1000 nm, placing the support substrate in the film-forming chamber and forming the non-single-crystal semiconductor film, and melting and recrystallizing the non-single-crystal semiconductor film by heating.

6. The manufacturing method according to claim 5, further comprising subjecting the inner wall to a baking process in a temperature range of 80 to 150° C.

7. The manufacturing method according to claim 5, wherein energy light is radiated to heat the non-single-crystal semiconductor film.

8. The manufacturing method according to claim 5, wherein the non-single-crystal semiconductor film is heated for a heating time of 10 seconds or less at a heating place.

9. The manufacturing method according to claim 7, wherein the heating time is one second or less.

10. A manufacturing apparatus for a semiconductor structure having a non-single-crystal semiconductor film including a channel region for an active device, and a support substrate that supports the non-single-crystal semiconductor film, the apparatus comprising a film-forming unit that accommodates the support substrate in a film-forming chamber and forms the non-single-crystal semiconductor film, and a crystallizing unit that melts and recrystallizes the non-single-crystal semiconductor film, the film-forming chamber having an inner wall formed of a metal containing aluminum.

11. The manufacturing apparatus according to claim 10, wherein a surface of the inner wall includes fluorine atoms and is coated with an amorphous semiconductor film with a thickness of 50 to 1000 nm.

12. A semiconductor device comprising a non-single-crystal semiconductor film, a support substrate that supports the non-single-crystal semiconductor film, and an active device having a part of the non-single-crystal semiconductor film as a channel region, the channel region having an oxygen concentration not higher than 1×10¹⁸ atoms/cm³ and a carbon concentration not higher than 1×10¹⁸ atoms/cm³.

13. The semiconductor device according to claim 12, wherein the active device is a thin-film transistor including source and drain regions disposed on both sides of the channel region in the non-single-crystal semiconductor film, and a gate electrode layer insulated from the channel region by an insulation film.

14. The semiconductor device according to claim 13, wherein the channel region is located within a single crystal grain that has a growth direction coinciding with a direction of arrangement of the source and drain regions.

15. The semiconductor device according to claim 12, wherein each of the oxygen concentration and the carbon concentration is not higher than 5×10¹⁷ atoms/cm³.

16. The semiconductor device according to claim 12, wherein the non-single-crystal semiconductor film includes a metal element with a concentration not higher than 1×10¹⁷ atoms/cm³.

17. The semiconductor device according to claim 16, wherein the concentration of the metal element is not higher than 5×10¹⁶ atoms/cm³.

18. A semiconductor device comprising a non-single-crystal semiconductor film, a support substrate that supports the non-single-crystal semiconductor film, and an active device having a part of the non-single-crystal semiconductor film as a channel region, the channel region having an oxygen concentration not higher than 1×10¹⁸ atoms/cm³ and a stacking fault density not higher than 1×10⁶ cm⁻³.

19. A manufacturing method for a semiconductor device having a non-single-crystal semiconductor film, a support substrate that supports the non-single-crystal semiconductor film, and an active device having a part of the non-single-crystal semiconductor film as a channel region, the method comprising subjecting an inner wall of a film-forming chamber to a surface etching process with a fluorine-based gas, coating the inner wall with an amorphous semiconductor film with a thickness of 50 to 1000 nm, placing the support substrate in the film-forming chamber and forming the non-single-crystal semiconductor film, and melting and recrystallizing the non-single-crystal semiconductor film, thus forming the active device having the part of the non-single-crystal semiconductor film as the channel region.
